(19) United States
(12) Patent Application Publication
(10) Pub. No.: US 2026/0282909 A1
(43) Pub. Date: Sep. 17, 2026

(54) COMPOSITE COOLING DISK FOR CONTINUOUS TRANSIENT COOLING FOR SEMICONDUCTOR CHIP

(71) Applicant: Western Digital Technologies, Inc., San Jose, CA (US)

(72) Inventors: Toshiki Hirano, San Jose, CA (US); Hussam Zebian, Milpitas, CA (US); Dejan Vucinic, Gilroy, CA (US); Zvonimir Bandic, San Jose, CA (US)

(21) Appl. No.: 19/679,523

(22) Filed: May 15, 2026

Related U.S. Application Data
(63) Continuation-in-part of application No. 19/019,098, filed on Jan. 13, 2025.
(60) Provisional application No. 63/995,748, filed on Mar. 3, 2026.

(51) Int. Cl. H10W 40/25; H10W 40/20; H10W 40/22; H10W 40/43; H10W 40/47; H10W 40/73

(52) U.S. Cl. CPC H10W 40/255; H10W 40/22; H10W 40/233; H10W 40/251; H10W 40/43; H10W 40/47; H10W 40/73

(57) ABSTRACT

Removing heat from a heat-generating device, such as a semiconductor chip, involves a cooling system that includes a thermally conductive solid structure configured for moving over the device, and a liquid metal between the solid structure and the device. Movement of the structure over a heat-emanating surface of the device facilitates transfer of heat generated by the device to the structure via the liquid metal, and physically moves that heat away from the device. Because the solid structure is continuously moving, a continuous cycle of heat transfer, physical movement, and dissipation for cooling the heat-generating device is provided. The cooling structure includes a first portion including a thermally conductive first material having a first density and a second portion including a second material having a second density less than the first density, to provide a lighter composite cooling structure and thus reduce support bearing loads.

### FIELD OF EMBODIMENTS

Embodiments of the invention may relate generally to electronics equipment, and particularly to approaches to cooling semiconductor chips.

### BACKGROUND

It is well-known that electronics, such as those used in data storage and data processing, consume a significant amount of power. Likewise, it is well-known that such power is dissipated in the form of heat, which requires significant cooling and related costs. Recent semiconductor chips (e.g., CPUs (Central Processing Units) and GPUs (Graphics Processing Units)) are consuming more and more power, and the consequent heat generated needs to be removed from the chips by some approach to and/or device for cooling so that the chip temperature remains below its corresponding limit (e.g., typically around 100° Celsius). However, current cooling devices often reach their limits and chips must be “throttled” (i.e., performance reduced) to maintain temperatures below their respective temperature limits. Such throttling results in chip performance degradation.

Any approaches that may be described in this section are approaches that could be pursued, but not necessarily approaches that have been previously conceived or pursued. Therefore, unless otherwise indicated, it should not be assumed that any of the approaches described in this section qualify as prior art merely by virtue of their inclusion in this section.

### BRIEF DESCRIPTION OF THE DRAWINGS

Embodiments are illustrated by way of example, and not by way of limitation, in the figures of the accompanying drawings and in which like reference numerals refer to similar elements and in which:

FIG. 1 is a diagram illustrating an electronics cooling system, according to an embodiment;

FIG. 2 is a diagram illustrating an electronics cooling system with external heat dissipator, according to an embodiment;

FIG. 3A is a diagram illustrating a parallel solid conductive structure for an electronics cooling system, according to an embodiment;

FIG. 3B is a diagram illustrating a perpendicular solid conductive ring structure for an electronics cooling system, according to an embodiment;

FIG. 3C is a diagram illustrating a solid conductive structure at an acute angle for an electronics cooling system, according to an embodiment;

FIG. 4A is a diagram illustrating a parallel translating solid conductive structure for an electronics cooling system, according to an embodiment;

FIG. 4B is a diagram illustrating a perpendicular translating solid conductive structure for an electronics cooling system, according to an embodiment;

FIG. 5A is a diagram illustrating a perpendicular solid conductive structure with heat-conducting appendages for an air-cooled electronics cooling system, according to an embodiment;

FIG. 5B is a diagram illustrating a perpendicular solid conductive structure for a liquid-cooled electronics cooling system, according to an embodiment;

FIG. 6 is a diagram illustrating a parallel solid conductive structure configured for a fluid dynamic bearing for an electronics cooling system, according to an embodiment;

FIG. 7 is a flow diagram illustrating a method for removing heat from a heat-generating device, according to an embodiment;

FIG. 8 is a side view diagram illustrating a composite cooling structure for an electronics cooling system, according to an embodiment;

FIG. 9A is a top view diagram illustrating a composite cooling disk for an electronics cooling system, according to an embodiment;

FIG. 9B is a cross-sectional side view diagram illustrating a composite cooling disk of FIG. 9A, according to an embodiment;

FIG. 9C is a cross-sectional side view diagram illustrating a composite cooling disk of FIG. 9A, according to an embodiment;

FIG. 10A is a perspective view diagram illustrating a composite cooling cylinder for an electronics cooling system, according to an embodiment;

FIG. 10B is a cross-sectional perspective view diagram illustrating the composite cooling cylinder of FIG. 10A, according to an embodiment;

FIG. 10C is a perspective view diagram illustrating an electronics cooling system including the composite cooling cylinder of FIG. 10A, according to an embodiment;

FIG. 10D is a side view diagram illustrating a heat source interface for the electronics cooling system of FIG. 10C, according to an embodiment;

FIG. 11A is a top view diagram illustrating a composite cooling disk with a degree of freedom for an electronics cooling system, according to an embodiment;

FIG. 11B is a side view diagram illustrating the composite cooling disk of FIG. 11A, according to an embodiment;

FIG. 11C is a top view diagram illustrating a hollowed composite cooling structure with a degree of freedom for an electronics cooling system, according to an embodiment; and

FIG. 12 is a flow diagram illustrating a method for removing heat from a heat-generating device, according to an embodiment.

### DETAILED DESCRIPTION

Approaches to cooling semiconductor chips are described. In the following description, for the purposes of explanation, numerous specific details are set forth to provide a thorough understanding of the embodiments of the invention described herein. It will be apparent, however, that the embodiments of the invention described herein may be practiced without these specific details. In other instances, well-known structures and devices are shown in block diagram form to avoid unnecessarily obscuring the embodiments of the invention described herein.

### INTRODUCTION

### Terminology

References herein to “an embodiment”, “one embodiment”, and the like are intended to mean that the particular feature, structure, or characteristic being described is included in at least one embodiment of the invention. However, instances of such phrases do not necessarily all refer to the same embodiment.

If used herein, the term “substantially” will be understood to describe a feature that is largely or nearly structured, configured, dimensioned, etc., but with which manufacturing tolerances and the like may in practice result in a situation in which the structure, configuration, dimension, etc. is not always or necessarily precisely as stated. For example, describing a structure as “substantially vertical” would assign that term its plain meaning, such that the structure is vertical for all practical purposes but may not be precisely at 90 degrees throughout.

While terms such as “optimal”, “optimize”, “minimal”, “minimize”, “maximal”, “maximize”, and the like may not have certain values associated therewith, if such terms are used herein the intent is that one of ordinary skill in the art would understand such terms to include affecting a value, parameter, metric, and the like in a beneficial direction consistent with the totality of this disclosure. For example, describing a value of something as “minimal” does not require that the value actually be equal to some theoretical minimum (e.g., zero) but should be understood in a practical sense in that a corresponding goal would be to move the value in a beneficial direction toward a theoretical minimum.

### Context

Semiconductors are the basic materials needed to make integrated circuits and what are commonly referred to as “chips”. A chip is a carrier composed of a semiconductor material on which multiple electronic components are integrated, e.g., transistors, resistors, capacitors, etc. used to perform various circuit functions. Recall that electronics, and high-power semiconductor chips in particular, tend to consume a significant amount of power, and that such power is dissipated in the form of heat. There are several known approaches to high-power chip cooling, such as conduction with forced air cooling, circulating liquid cooling, and evaporation with forced air cooling. To avoid chip throttling and consequent chip performance degradation, higher chip cooling performance may be desired.

### Continuous Transient Heat Removal by Solid-Convection

The performance of conventional water cooling is limited based at least in part on the relatively low thermal conductivity of water (around 0.6 W/mK (Watts per meter-Kelvin)). For example, for 1000 W/cm² (Watts/centimeter squared) thermal flow and a 40° C. (Celsius) temperature gradient, the heat can only penetrate about 2 μm (micrometer, or micron) into the coolant water and, furthermore, the water within a few microns from the water container wall barely moves due to viscosity. Thus, water cooling presents a relatively low heat removal capability. By contrast, conceptually replacing water with a solid material such as copper (referred to herein as “solid convection” cooling, or “continuous transient” cooling), which has a relatively high thermal conductivity (around 400 W/mK, approaching 700 times better than water). Thus, for example, for 1000 W/cm² thermal flow and a 40° C. temperature gradient, the heat can penetrate about 1.6 mm (millimeter) into the solid copper and, furthermore, the copper can be passed over the heat source at a constant, high speed. Thus, a moving, highly thermally conductive solid cooling material presents a relatively high heat removal capability.

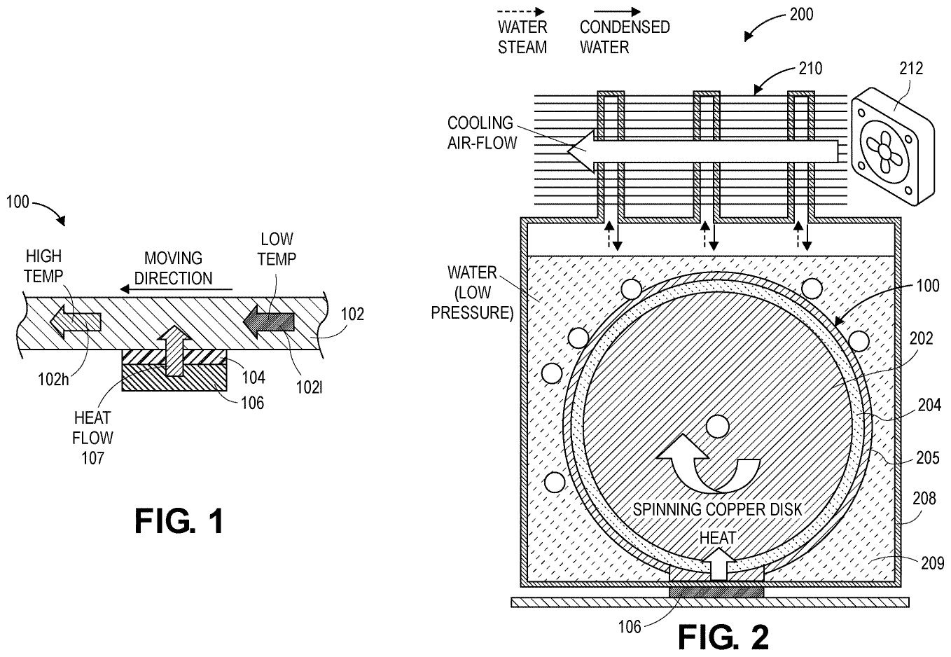

FIG. 1 is a diagram illustrating an electronics cooling system, according to an embodiment. The cooling system 100 of FIG. 1 assists in characterizing an approach to cooling, according to embodiments, in which heat is removed from a heat-generating device whereby the heat is carried away from the device by a moving high-thermal-conductivity solid through a high-thermal-conductivity liquid positioned between the device and the solid. Thus, this approach may be characterized as a “solid-convection” process, whereby heat is transferred by the movement of a solid form of material rather than by movement of a liquid or gas as with the conventional, naturally-occurring form of convection. Regardless of terminology that may be preferred, the approach functions as follows.

Cooling system 100 comprises a highly-thermally conductive solid structure 102 configured to move over a surface of a heat-generating device 106, and a highly-thermally conductive liquid metal 104 (e.g., at least for cooling and for lubrication) positioned between the solid structure 102 and the heat-generating device 106. Consequently, movement of the solid structure 102 over a heat-emanating surface of the heat-generating device 106 facilitates, encourages, promotes the transfer of heat generated by the heat-generating device 106 to the solid structure 102 via the liquid metal 104, and physically moves the heat transferred to the solid structure 102 away from the heat-generating device 106.

For example, a low temperature portion 1021 of a substantially continuously moving solid structure 102 (e.g., copper) is moved toward the heat-generating device 106 (e.g., a semiconductor-based chip). In response to the low temperature portion 1021 moving in closer proximity to and over the heat-generating device 106, heat generated by the heat-generating device 106 flows/conducts (represented by block arrow 107) from the heat-generating device 106 through the liquid metal 104 (e.g., Indium-Gallium (InGa) alloy) to the solid structure 102, thereby forming/generating a high temperature portion 102h of (e.g., a hot spot on) the moving solid structure 102. In turn, because the solid structure 102 is continuously moving, the high temperature portion 102h is now moving away from the heat-generating device 106 and therefore carries/transports the heat (hot spot) away from the heat-generating device 106. Also, because the solid structure 102 is continuously moving, this is a continuous cycle of heat transfer, physical movement (e.g., dynamic, transient), and dissipation for cooling the heat-generating device 106. Preferably, such a thermodynamic-mechanical cycle should be designed and implemented such that the high temperature portion 102h is cooled down to an appropriate temperature to serve as the low temperature portion 1021 according to, for non-limiting examples, a desired cycle-time relative to the amount of heat being removed, a number of passings over the heat-generating device 106, and the like. This may manifest in, for example, a preferred revolutions per second in the context of a revolving solid structure 102. This process is considered especially applicable and beneficial for cooling ultra-high heat flux devices such as some CPUs and GPUs, although implementation is not limited thereto.

While copper may be a preferred material to implement for use as the highly thermally-conductive solid structure 102, the use of other highly thermally-conductive materials such as steel, brass, silver, and the like is also contemplated. Furthermore, while an InGa alloy such as Indium-Gallium-Tin (InGaSn) may be a preferred material to implement for use as the highly thermally-conductive liquid metal 104 (e.g., a thermal interface material, or “TIM”), the use of other highly thermally-conductive liquid thermal interface materials such as mercury and the like is also contemplated. Note that not only does the liquid metal 104 provide a heat-conductive path between the heat-generating device 106 and the solid structure 102 (as a highly thermally-conductive material), the liquid metal 104 also functions as a lubricant to minimize friction between the two bodies (as a liquid). The liquid metal 104 TIM between the heat-generating device 106 and the solid structure 102 is preferably very thin (e.g., less than 0.1 mm (millimeter)) and preferably has relatively high thermal conductivity (e.g., more than 10 W/mK (watts per meter per degree Kelvin)).

### Augmented Cooling

While the heat transferred from the heat-generating device 106 to the solid structure 102 is expected to naturally move and dissipate within the body of the solid structure 102 via conduction and without the body of the solid structure 102 via conduction and/or convection to the surrounding environment, one or more augmented cooling systems may be implemented in conjunction with a system such as cooling system 100. Any of the various known cooling techniques may be implemented to assist in cooling of the solid structure 102, such as circulating water cooling, direct air cooling with fins and fan(s), non-water (e.g., fluorocarbon) boiling liquid cooling, or a combination of any of the foregoing, for non-limiting examples.

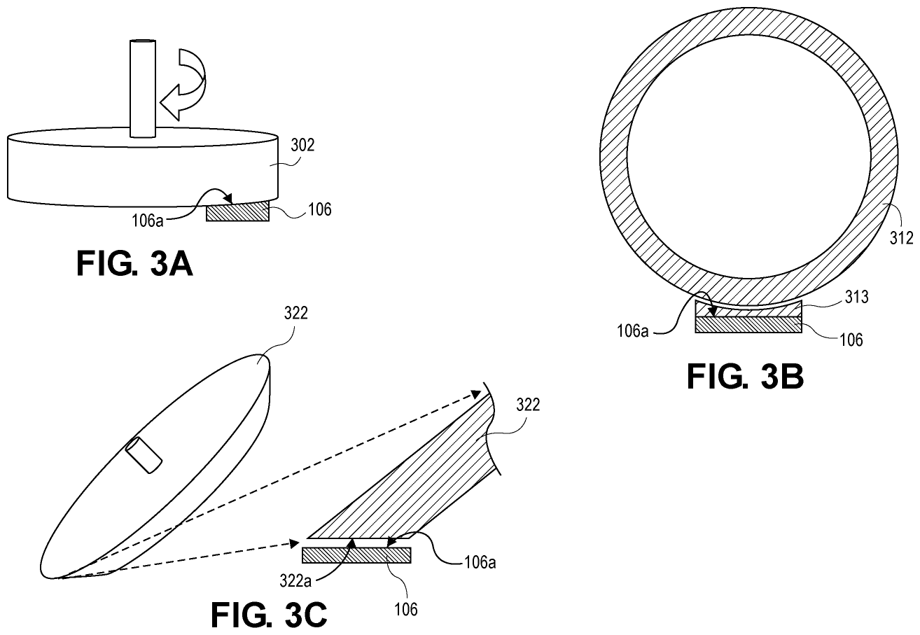

FIG. 2 is a diagram illustrating an electronics cooling system with external heat dissipator, according to an embodiment. Augmented cooling system 200 (“cooling system 200”) is an example that may be implemented to assist in removing the transferred heat (from heat-generating device 106) from the solid structure 102. Cooling system 200 comprises an implementation of cooling system 100 (FIG. 1) in thermal communication with a heat-generating device 106, housed in an enclosure 205, and immersed in a chamber 208 filled with water 209 at low pressure. This example of a cooling system 100 comprises a spinning (revolving) copper disk 202 (“disk 202”) housed in the enclosure 205 along with a liquid metal 204, where the enclosure 205 is in thermally-conductive communication with the heat-generating device 106. Alternatively to a disk, a thicker solid structure (e.g., a drum) may be used for solid structure 102. Preferably, the enclosure 205 walls are very thin (e.g., less than 1 mm) and with relatively high thermal conductivity (e.g., more than 100 W/mK). Cooling system 200 further comprises a condenser 210 coupled with the chamber 208 and a corresponding cooling fan 212 external to the chamber 208.

In this context, heat is removed from the heat-generating device 106 (e.g., a high-power chip) to the environment in a continuous cycle as follows. As described generally in reference to cooling system 100 of FIG. 1, heat moves from the heat-generating device 106 to the spinning copper disk 202 through the enclosure 205 and the liquid metal 204. As such, the heat creates a “hot spot” on the disk 202 surface. The disk 202 is constantly rotating, thus the hot spot is quickly removed from the heat-emanating surface of heat-generating device 106. The hot-spot is cooled by the evaporation of the low-pressure water 209 outside of the disk 202 and enclosure 205. Evaporated water (or steam) goes into the condenser 210, over which cooling airflow is blown by the fan 212, and is condensed back to liquid water, which returns back into the chamber 208. By repeating these steps, the chip always receives cold copper surface that provides efficient heat conduction, e.g., “continuous transient cooling”.

### Solid-Convection Structure Examples

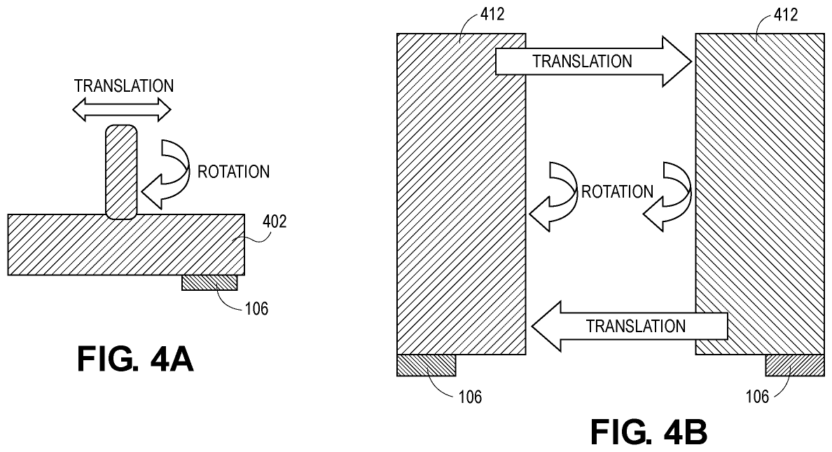

In addition to the high-thermal-conductivity material used, the shape, dimensions, orientation, etc. (generally “configuration”) of a solid structure 102 may also vary from implementation to implementation based on the design goals and constraints. FIGS. 3A-3C illustrate some non-limiting examples of configurations for a solid structure 102 for implementation in a cooling system 100 as illustrated and described in reference to FIG. 1.

FIG. 3A is a diagram illustrating a parallel solid conductive structure for an electronics cooling system, according to an embodiment. According to this embodiment, a solid structure 302 comprises a disk-shaped structure (“disk 302”) positioned in a plane substantially parallel to a primary heat-emanating surface 106a of the heat-generating device 106, and the disk 302 is configured to rotate, revolve, spin in the plane such that a portion of the disk 302 passes over the primary heat-emanating surface 106a of the heat-generating device 106 for the purposes described herein. Such a horizontal orientation is in contrast with the vertical orientation illustrated in reference to solid structure 202 of FIG. 2. Any conventional or known form of motor or driving mechanism may be utilized to revolve the disk 302 in the plane of the disk 302. According to an embodiment and as illustrated in FIG. 3A, the portion of disk 302 that passes over the primary heat-emanating surface 106a of the heat-generating device 106 is a radially outer portion of the disk.

FIG. 3B is a diagram illustrating a perpendicular solid conductive ring structure for an electronics cooling system, according to an embodiment. According to this embodiment, a solid structure 312 comprises an annular or ring-shaped structure (“ring 312”) positioned in a plane substantially normal (perpendicular) to the primary heat-emanating surface 106a of the heat-generating device 106, and the ring 312 is configured to rotate, revolve, spin in the plane such that an outer circumferential edge of the ring 312 passes over the primary heat-emanating surface 106a of the heat-generating device 106 for the purposes described herein. Such a vertical orientation is consistent with the vertical orientation illustrated in reference to solid structure 202 of FIG. 2. Here also, any conventional or known form of motor or driving mechanism may be utilized to revolve the ring 312 in the plane of the ring 312. According to an embodiment, an additional metal thermal bridge 313 having a concave surface may be positioned between the heat-emanating surface 106a of the heat-generating device 106 and the ring 312, to maintain a small gap between to facilitate the transfer of heat from the heat-generating device 106 to the similarly-curved outer rim of vertically-oriented ring 312. Such a thermal bridge 313 is not necessary for the disk 302 embodiment of FIG. 3A because the heat-receiving surface of the disk 302 is parallel to the heat-emanating surface 106a.

FIG. 3C is a diagram illustrating a solid conductive structure at an acute angle for an electronics cooling system, according to an embodiment. According to this embodiment, a solid structure 322 comprises canted disk-shaped structure (“canted disk 322”) positioned in a plane at an acute angle to the primary heat-emanating surface 106a of the heat-generating device 106, and the canted disk 322 is configured to rotate, revolve, spin in the plane such that an outer circumferential portion of the canted disk 322 passes over the primary heat-emanating surface 106a of the heat-generating device 106 for the purposes described herein. Such an angled, canted orientation may be preferred over a vertical orientation if there are vertical space constraints in the installation environment. Here also, any conventional or known form of motor or driving mechanism may be utilized to revolve the canted disk 322 in the plane of the canted disk 322. According to an embodiment, the outer circumferential portion/edge of the canted disk 322 comprises a chamfered surface 322a substantially parallel to the primary heat-emanating surface 106a of the heat-generating device 106.

### Translating Solid-Convection Structure

In addition to rotating, revolving, spinning the heat-absorbing solid structure such as solid structure 102 (FIG. 1), 202 (FIG. 2), 302 (FIG. 3A), 312 (FIG. 3B), 322 (FIG. 3C), the solid structure may be configured for translation over the heat-emanating surface 106a of the heat-generating device 106.

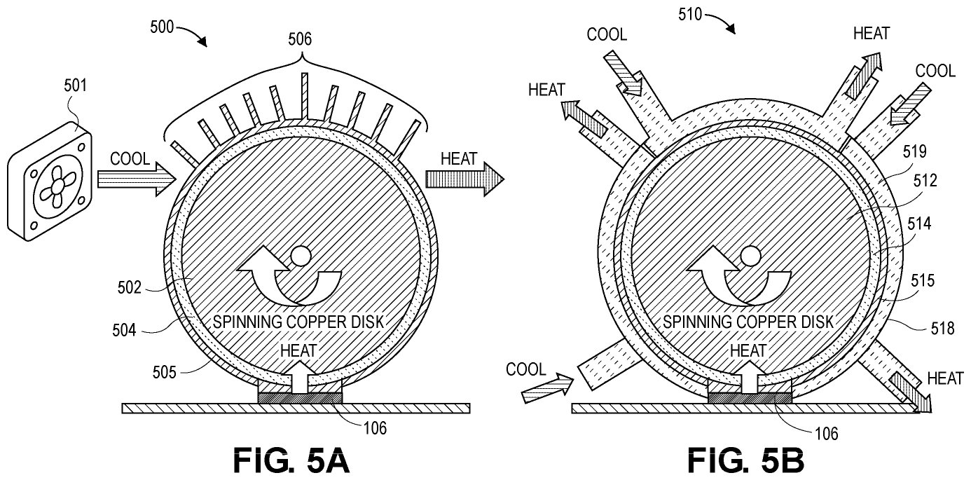

FIG. 4A is a diagram illustrating a parallel translating solid conductive structure for an electronics cooling system, according to an embodiment. According to an embodiment, after some certain time less than the time constant of the system (e.g., after one horizontal rotation of a solid structure 402, here “disk 402”), the disk 402 is translated (e.g., moved sideways) so that the heat-generating device 106 encounters “fresh” portion(s) of the high-thermal-conductivity solid disk 402. For example, the entire disk 402 enclosure (see, e.g., enclosure 205 of FIG. 2) may be translated over the heat-generating device 106, or the disk 402 may be moved within the corresponding enclosure. Thus, the heat-generating device 106 contacts the disk 402 at different radii from the center of rotation.

FIG. 4B is a diagram illustrating a perpendicular translating solid conductive structure for an electronics cooling system, according to an embodiment. According to an embodiment, after some certain time less than the time constant of the system (e.g., after one vertical rotation of a solid structure 412, here “disk 412”), the disk 412 is translated (e.g., moved sideways) so that the heat-generating device 106 encounters “fresh” portion(s) of the high-thermal-conductivity solid disk 412. For example, the entire disk 412 enclosure (see, e.g., enclosure 205 of FIG. 2) may be translated over the heat-generating device 106, or the disk 412 may be moved within the corresponding enclosure. Thus, the heat-generating device 106 contacts the disk 412 at different portions of the circumferential edge of the disk 412. With this embodiment, a thicker disk 412 (e.g., a drum or cylinder) may be employed, thus resulting in more rotations before translating back to a prior position over the heat-generating device 106.

### Augmenting Cooling System Examples

As illustrated and described in reference to FIG. 2, an external cooling system (see, e.g., augmented cooling system 200) may be implemented with an augmenting cooling system to assist in removing the transferred heat (from heat-generating device 106) from the corresponding solid structure 102 (FIG. 1), 202 (FIG. 2), 302 (FIG. 3A), 312 (FIG. 3B), 322 (FIG. 3C), 402 (FIG. 4A), 412 (FIG. 4B).

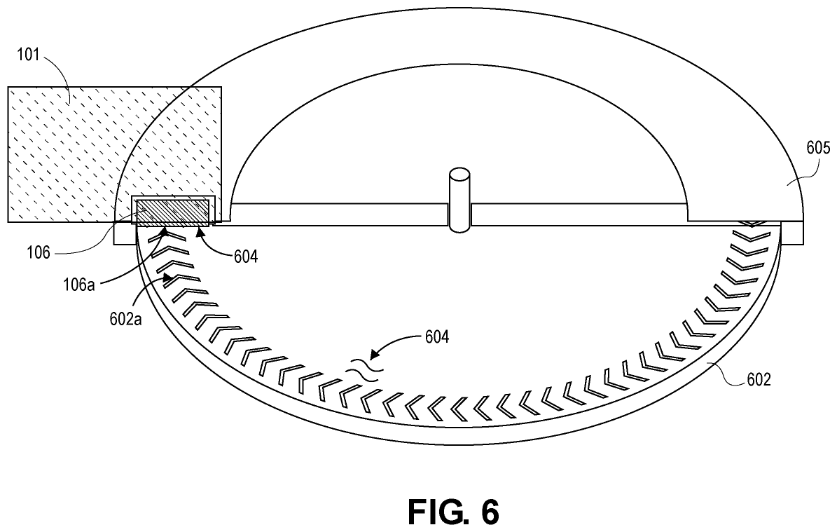

FIG. 5A is a diagram illustrating a perpendicular solid conductive structure with heat-conducting appendages for an air-cooled electronics cooling system, according to an embodiment. Air-cooled cooling system 500 comprises an implementation of cooling system 100 (FIG. 1) in thermal communication with a heat-generating device 106. This example of a cooling system 500 comprises a spinning (revolving) copper disk 502 (“disk 502”) housed in an enclosure 505 along with a liquid metal 504, where the enclosure 505 is in thermally-conductive communication with the heat-generating device 106. In the embodiment illustrated, enclosure 505 further comprises a set of heat-conducting appendages 506 (e.g., “fins”) coupled with the enclosure 505. Here, a corresponding cooling fan 501 external to the enclosure 505 is utilized to blow cool air over the appendages 506. Additionally, or alternatively, heat-conducting appendages may be implemented directly onto the outer perimeter of the disk 502 and/or on the inside of enclosure 505, to increase the surface area of heat exchange at hot location(s) of disk 502.

FIG. 5B is a diagram illustrating a perpendicular solid conductive structure for a liquid-cooled electronics cooling system, according to an embodiment. Liquid-cooled cooling system 510 comprises an implementation of cooling system 100 (FIG. 1) in thermal communication with a heat-generating device 106. This example of a cooling system 510 comprises a spinning (revolving) copper disk 512 (“disk 512”) housed in an enclosure 515 along with a liquid metal 514, where the enclosure 515 is in thermally-conductive communication with the heat-generating device 106. In the embodiment illustrated, the enclosure 515 (and the corresponding internal components) is immersed in a chamber 518 filled with a cooling liquid 519 (water, liquid metal, fluorocarbon, etc.). Shown here are multiple entry and exit points for the cooling liquid 519, for purposes of more efficient cooling. However, a single entry and exit point may be implemented.

### Liquid Metal as Fluid Dynamic Bearing

As described in reference to FIG. 1, the liquid metal 104 (TIM) between the heat-generating device 106 and the solid structure 102 is preferably very thin (e.g., less than 0.1 mm). Thus, according to an embodiment, a fluid dynamic bearing is employed on the interface surface to precisely maintain a small gap between the heat-generating device 106 and the solid structure 102. A fluid dynamic bearing (FDB), also referred to as a hydrodynamic bearing, is a type of non-contact bearing in which the load is supported by a thin layer of rapidly moving liquid (or gas) between the bearing surfaces.

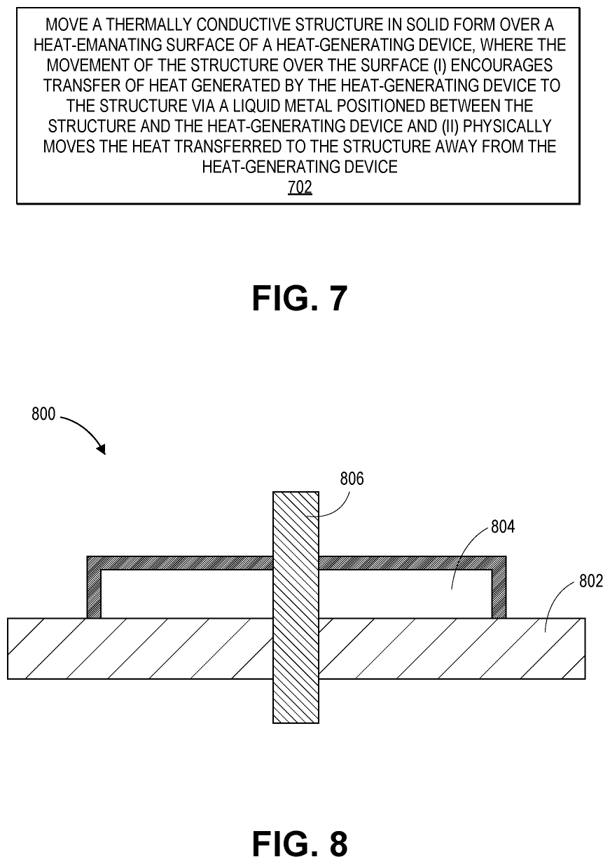

FIG. 6 is a diagram illustrating a parallel solid conductive structure configured for a fluid dynamic bearing for an electronics cooling system, according to an embodiment. To precisely maintain a small gap between the heat-generating device 106 and the solid structure 602, the solid structure 602 (e.g., “disk 602”) comprises a series of etchings 602a (or protrusions) around the portion of the disk 602, where the series of etchings 602a is configured to move the liquid metal 604 in such a way so that the liquid metal 604 functions as a FDB between the rotating disk 602 and a heat-generating device 106 (e.g., a chip) of an electronic device 101.

### Method for Removing Heat from a Heat-Generating Device

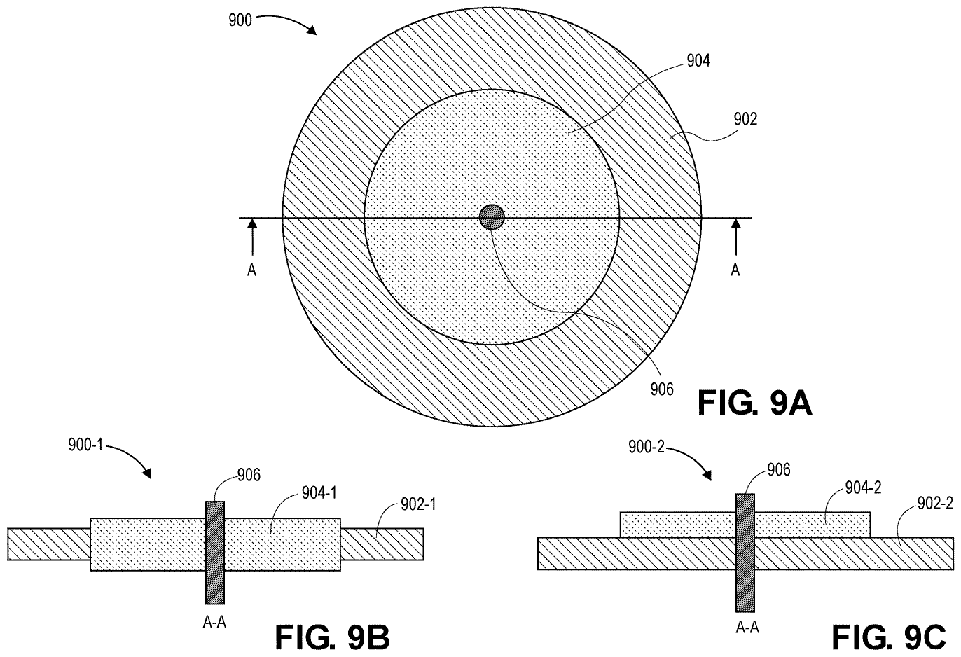

FIG. 7 is a flow diagram illustrating a method for removing heat from a heat-generating device, according to an embodiment. The method of FIG. 7 characterizes a method for removing heat by way of a cooling system such as cooling system 100 of FIG. 1.

At block 702, move a thermally conductive structure in solid form over a heat-emanating surface of a heat-generating device, where the movement of the structure over the heat-emanating surface of the heat-generating device (i) encourages transfer of heat generated by the heat-generating device to the structure via a liquid metal positioned between the structure and the heat-generating device and (ii) physically moves the heat transferred to the structure away from the heat-generating device. For example, moving solid structure 102 (FIG. 1), 202 (FIG. 2), 302 (FIG. 3A), 312 (FIG. 3B), 322 (FIG. 3C), 402 (FIG. 4A), 412 (FIG. 4B), 502 (FIG. 5A), 512 (FIG. 5B) over a heat-emanating surface 106a of a heat-generating device 106, whereby the movement of the structure 102, 202, 302, 312, 322, 402, 412, 502, 512 over the heat-emanating surface 106a of the heat-generating device 106 (i) encourages transfer of heat generated by the heat-generating device 106 to the structure 102 et seq. via a liquid metal 104 (FIG. 1), 204 (FIG. 2), 504 (FIG. 5A), 514 (FIG. 5B), 604 (FIG. 6) positioned between the structure 102 et seq, and the heat-generating device 106 and (ii) physically moves the heat transferred to the structure 102 et seq. away from the heat-generating device 106.

As described elsewhere herein, according to an embodiment, moving the thermally conductive structure (block 702) may include rotating a disk structure positioned in a plane substantially parallel to the heat-emanating surface 106a of the heat-generating device 106 (see, e.g., solid structure 102 (FIG. 1), 302 (FIG. 3A), 402 (FIG. 4A), 602 (FIG. 6)) such that a portion of the disk structure passes over the heat-emanating surface 106a of the heat-generating device 106. As described elsewhere herein, according to an embodiment, moving the thermally conductive structure (block 702) may include rotating a disk structure positioned in a plane at an angle to the heat-emanating surface 106a of the heat-generating device 106 (see, e.g., solid structure 102 (FIG. 1), 202 (FIG. 2), 312 (FIG. 3B), 322 (FIG. 3C), 412 (FIG. 4B), 502 (FIG. 5A), 512 (FIG. 5B)), such that an outer circumferential edge of the disk passes over the heat-emanating surface 106a of the heat-generating device 106. Furthermore, and as described elsewhere herein, according to an embodiment, moving the thermally conductive structure (block 702) may include translating the structure back and forth over the surface of the heat-generating device (see, e.g., solid structure 402 (FIG. 4A), 422 (FIG. 4B)).

### Composite Moving Cooling Disk for Continuous Transient Cooling

As illustrated and described in reference to FIGS. 2-7, a translating solid conductive structure, such as a cooling disk, ring, cylinder, drum, and the like, can be employed in an electronics cooling system to remove, move, and dissipate heat from a heat-generating device (a “heat source”) such as a semiconductor chip. In that context, the solid conductive structure (e.g., copper) that removes the heat from the heat source needs to be movable and thus likely relies on bearings for support. Due to the heavy weight of a solid conductive structure, the load on the bearing(s) can be significant, which can thereby result in a reduced lifetime of the cooling system caused by bearing failure.

Additionally, such a large amount of metal for a solid conductive structure can carry a non-trivial cost, and such a heavy structure can result in a slower response to spin up and down (e.g., possibly requiring a more costly motor), challenges generating adequate lift force via a fluid dynamic bearing, and challenges with parking the structure at shutdown, for non-limiting examples. Further, in the context of applications in space, weight is of significant concern due to the cost of deployment. However, simply reducing the radius of the cooling structure to reduce its weight would reduce the cooling performance as there is a linear relationship between disk radius and cooling performance, and reducing the thickness of the cooling structure would reduce the cooling performance as well as the disk stiffness, the latter of which can cause a cooling disk to flutter significantly thereby causing undesirable fluctuations in the designed clearance gaps.

In view of the foregoing challenges and according to embodiments, addition of a relatively light-weight material or a cavity to the moving solid conductive structure, e.g., an inhomogeneous disk, can be utilized to reduce the weight of a cooling disk that is employed in an electronics cooling system to remove, move, and dissipate heat from a heat-generating device (a “heat source”) such as a semiconductor chip. Here, “inhomogeneous” refers to a structure composed of different, mixed elements rather than a uniform composition, which indicates that properties (like density or composition) vary across different points. This type of structure is also referred to throughout herein as a “composite” structure, as its composition is made up of distinct parts or elements (i.e., materials) within its total volume.

According to embodiments, the addition of a light-weight material or a cavity to the moving solid cooling structure is configured such that the buoyancy created by the liquid metal in which the solid is submerged reduces the force to support the cooling structure. Where the average density (total weight/total volume) of the cooling structure is close to the surrounding liquid metal, the cooling structure effectively “floats” inside the liquid, and exerts a very small force to the supporting bearings. Consequently, bearing life can significantly improve, as the bearing life is shorter in scenarios in which the load is larger. Furthermore, a different kind of bearing can be used, such as a fluid dynamic bearing rather than a ball bearing.

The forces applied to the moving solid can be calculated as follows:

total weight of the solid=Vₛ*rₛ+Vₛ*rₐ, where (1)
Vₛ=volume of the solid,
rₛ=density of the solid,
Vₐ=volume of attached low-density material,
rₐ=density of attached low-density material; and

buoyancy of the solid=(Vₛ+Vₐ)*r₁, where (2)
r₁=density of liquid metal.
   The force required to support the moving solid in liquid metal is the difference of these two forces:

Fₛ=total weight of the solid-buoyancy=(Vₛ*rₛ+Vₐ*rₐ)−(Vₛ+Vₐ)*r₁. (3)

Thus, the volume of the attached low-density material can be adjusted to minimize the force to support the solid in the liquid metal:

0=(Vₛ*rₛ+Vₐ*rₐ)−(Vₛ+Vₐ)*r₁→Vₐ=(rₛ−r₁)/(r₁−rₐ)*Vₛ. (4)

Thus, according to an embodiment, the volume of the second material is configured such that the total weight of the cooling structure approximates or approaches the buoyant force (buoyancy) of the liquid metal in which the structure is submerged. Preferably, the volume of the second material is configured such that the total weight of the structure is close enough to the buoyant force of the liquid metal such that the force required to support the moving solid in the liquid metal is almost zero (e.g., neutral buoyancy), but this should be understood in a practical sense that a corresponding goal would be to attain a minimal or negligible force on the supporting bearings. However, any reduction in the weight of the cooling structure by way of implementing a light-weight material or a gas-filled cavity to the cooling structure should be understood to be beneficial in this context.

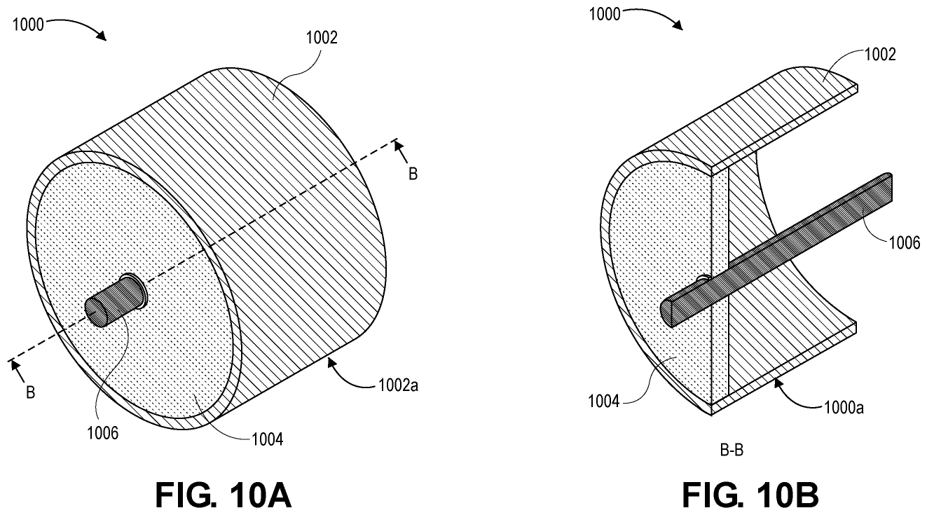

FIG. 8 is a side view diagram illustrating a composite cooling structure for an electronics cooling system, according to an embodiment. Composite cooling disk 800 (or simply “disk 800”) comprises a first portion 802 configured to be closer to a heat-generating device (not shown here; see, e.g., heat-generating device 106 of FIGS. 1-6), where the first portion 802 comprises a thermally conductive first material, i.e., a heat-removing solid, having a first density (e.g., copper). Disk 800 further comprises a second portion 804 configured to be farther from the heat-generating device, where the second portion 804 comprises a second material having a second density that is less than the first density. In the embodiment depicted, the second portion 804 comprises a cavity filled with a gas (e.g., air). Here, the cavity is preferably a hermetically sealed cavity to more readily maintain the gas within the cavity over time. Disk 800 further comprises a rotational shaft 806 configured for being driven (e.g., by a motor) to move disk 800 over a surface of a heat-generating device, where movement of the disk 800 over the surface facilitates transfer of heat generated by the heat-generating device to the disk 800 and physically moves the heat transferred to the disk 800 away from the heat-generating device.

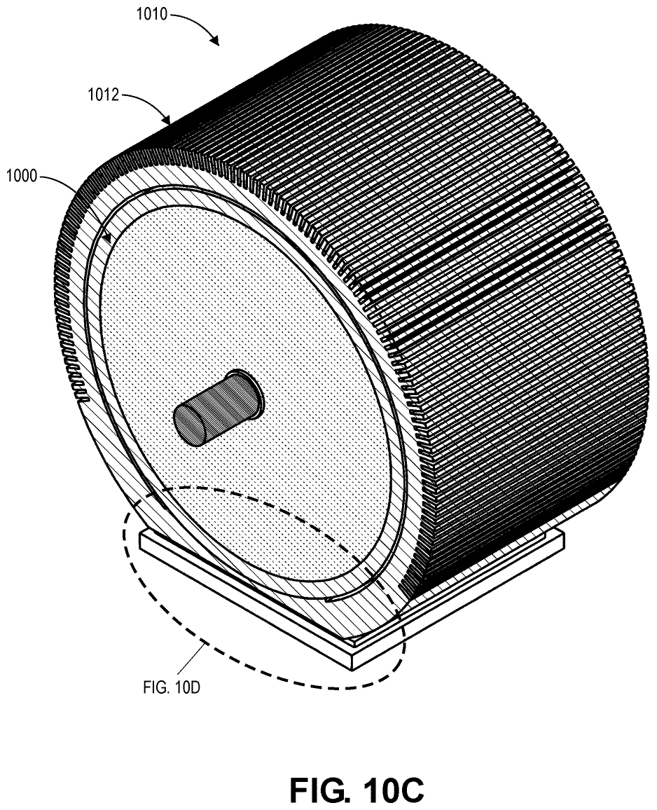

FIG. 9A is a top view diagram illustrating a composite cooling disk for an electronics cooling system, according to an embodiment. Composite cooling disk 900 (or simply “disk 900”) comprises a first portion 902 configured to be closer to a heat-generating device (not shown here; see, e.g., heat-generating device 106 of FIGS. 1-6), where the first portion 902 comprises a thermally conductive first material, i.e., a heat-removing solid, having a first density (e.g., copper). Disk 900 further comprises a second portion 904 configured to be farther from the heat-generating device, where the second portion 904 comprises a second material (e.g., a plastic, or glass) having a second density that is less than the first density. According to an embodiment, the disk 900 cooling structure is positioned in a plane substantially parallel to the heat-generating device and is configured to rotate in the plane such that at least a portion of the disk 900 passes over the surface of the heat-generating device. Disk 900 further comprises a rotational shaft 906 configured for being driven (e.g., by a motor) to move disk 900, primarily the first portion 902 of disk 900, over a surface of a heat-generating device, where movement of the disk 900 over the surface of the heat-generating device facilitates transfer of heat generated by the heat-generating device to the first portion 902 of disk 900 and physically moves the heat transferred to the disk 900 away from the heat-generating device.

FIG. 9B is a cross-sectional side view diagram illustrating a composite cooling disk of FIG. 9A, according to an embodiment. Composite cooling disk 900-1 (or simply “disk 900-1”) comprises a ring 902-1 configured to be closer to a heat-generating device, where the ring 902-1 comprises a thermally conductive first material having a first density, e.g., a heat-removing solid copper ring. Disk 900-1 further comprises a disk 904-1 disposed within the ring 902-1 and configured to be farther from the heat-generating device, where the disk 904-1 comprises a second material having a second density that is less than the first density.

FIG. 9C is a cross-sectional side view diagram illustrating a composite cooling disk of FIG. 9A, according to an embodiment. Composite cooling disk 900-2 (or simply “disk 900-2”) comprises a first disk 902-2 configured to be closer to a heat-generating device, where the disk 902-2 comprises a thermally conductive first material having a first density, e.g., a heat-removing solid copper disk. Disk 900-2 further comprises a second disk 904-2 coupled with the first disk 902-2 and configured to be farther from the heat-generating device, where the second disk 904-2 comprises a second material having a second density that is less than the first density.

### Composite Moving Cooling Cylinder for Continuous Transient Cooling

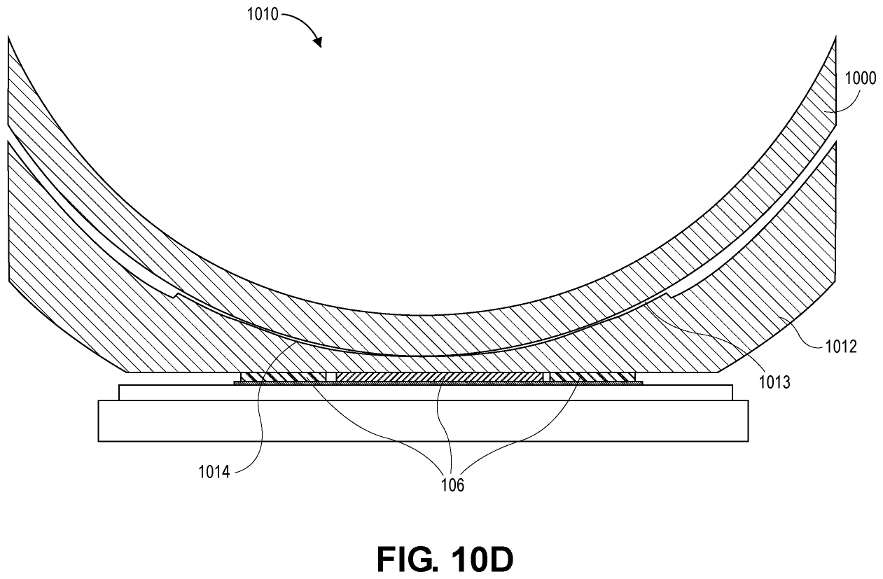

FIG. 10A is a perspective view diagram illustrating a composite cooling cylinder for an electronics cooling system, and FIG. 10B is a cross-sectional perspective view diagram illustrating the composite cooling cylinder of FIG. 10A, both according to embodiments. Composite cooling cylinder 1000 (or simply “cylinder 1000”) comprises a first portion 1002 configured to be closer to a heat-generating device (not shown here; see, e.g., heat-generating device 106 of FIGS. 1-6, 10D), where the first portion 1002 comprises a thermally conductive first material, i.e., a heat-removing solid, having a first density (e.g., copper). Disk 1000 further comprises a second portion 1004 configured to be farther from the heat-generating device, where the second portion 1004 comprises a second material (e.g., a plastic, or glass) having a second density that is less than the first density. According to an embodiment and as depicted, the first portion 1002 comprises an annular cylinder and the second portion 1004 comprises a disk disposed within the cylinder, at least in part to provide support for the annular cylinder and to facilitate driving via a shaft 1006. According to an embodiment, the cylinder 1000 cooling structure has a major axis (e.g., along the direction of shaft 1006) positioned substantially parallel to the surface of the heat-generating device, and cylinder 1000 is configured to rotate over the heat-generating device such that at least a portion of an outer surface 1002a of the cylinder 1000 passes over the surface of the heat-generating device. Cylinder 1000 further comprises the rotational shaft 1006 configured for being driven (e.g., by a motor) to move cylinder 1000 over a surface of a heat-generating device, where movement of the cylinder 1000 over the surface of the heat-generating device facilitates transfer of heat generated by the heat-generating device to the first portion 1002 of cylinder 1000 and physically moves the heat transferred to the cylinder 1000 away from the heat-generating device.

FIG. 10C is a perspective view diagram illustrating an electronics cooling system including the composite cooling cylinder of FIG. 10A, and FIG. 10D is a side view diagram illustrating a heat source interface for the electronics cooling system of FIG. 10C, both according to embodiments. Cooling system 1010 comprises the cylinder 1000 (FIGS. 10A-10B) disposed within a fixed annular outer housing 1012 (or “enclosure”), whereby cylinder 1000 is configured to be driven via shaft 1006 (FIGS. 10A-10B) to rotate within the fixed housing 1012. As depicted and according to an embodiment, housing 1012 may be augmented with cooling fins around a portion of the housing 1012. FIG. 10D illustrates how the housing 1012 may be fixedly positioned over the heat-generating device 106 (e.g., a group of semiconductor-based chips), with the cylinder 1000 rotatably housed therein along with a minute gap 1013 therebetween, in which a liquid 1014 such as a highly thermally conductive liquid metal is positioned. Here, the liquid 1014 can be utilized to provide lubrication and support (e.g., an FDB) for the rotating cylinder 1000, as well as to aid in the transfer of heat from heat-generating device 106 to the cylinder 1000 in the case of a conductive liquid metal.

### Degree of Freedom for Cooling Structures

In addition to lessening the load on any bearings providing support to any of the cooling structures described herein that employ the composite structure aspect of the cooling structures including a relatively lower density material than the density of the highly thermally conductive solid cooling structure (e.g., copper), providing a degree of freedom of movement to the conductive solid can be utilized to reduce fluid dynamic bearing (FDB) loads. As such, lowering the force requirement on any FDB can help forgo the complications of the shaft needing to move up and down during different fly-height or startup/shutdown operations.

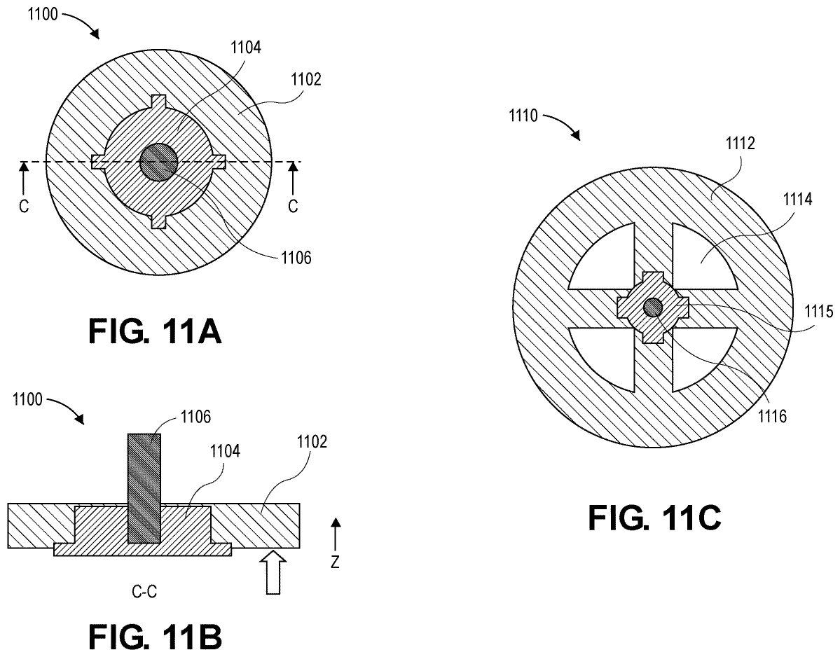

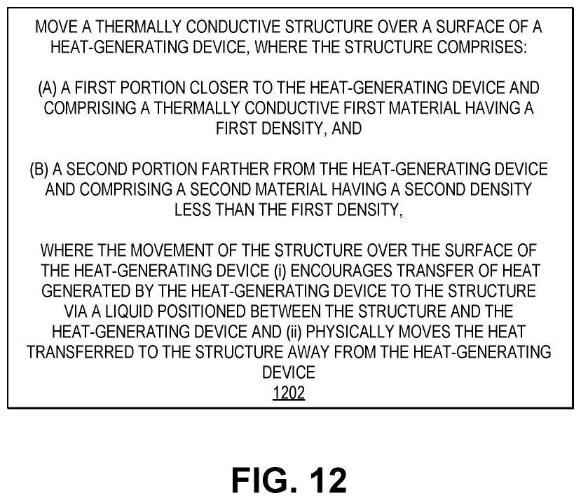

FIG. 11A is a top view diagram illustrating a composite cooling disk with a degree of freedom for an electronics cooling system, and FIG. 11B is a side view diagram illustrating the composite cooling disk of FIG. 11A, both according to embodiments. Similar to cooling disk 900 (FIG. 9A), composite cooling disk 1100 (or simply “disk 1100”) comprises a first portion 1102 configured to be closer to a heat-generating device (not shown here; see, e.g., heat-generating device 106 of FIGS. 1-6, 10D), where the first portion 1102 comprises a thermally conductive first material, i.e., a heat-removing solid, having a first density (e.g., copper). Disk 1100 further comprises a second portion 1104 configured to be farther from the heat-generating device, where the second portion 1104 comprises a second material (e.g., a plastic, or glass) having a second density that is less than the first density, and a rotational shaft 1106 configured for being driven (e.g., by a motor) to move disk 1100, primarily the first portion 1102 of disk 1100, over a surface of a heat-generating device, where movement of the disk 1100 over the surface of the heat-generating device facilitates transfer of heat generated by the heat-generating device to the first portion 1102 of disk 1100 and physically moves the heat transferred to the disk 1100 away from the heat-generating device.

Similar to cooling disk 900-1 (FIG. 9B, respectively), cooling disk 1100 comprises a ring 1102 comprising the thermally conductive first material having a first density (e.g., a heat-removing solid copper ring), and a disk 1104 movably disposed at least in part within the ring 1102 where the disk 1104 comprises the second material having a second density that is less than the first density. Here, a slot-and-key arrangement is utilized for the interface between the outer ring 1102 and the inner disk 1104, to enable a z-direction degree of freedom between the ring 1102 and the disk 1104. Thus, in response to any lift force (represented by block arrow) provided by an FDB, the ring 1102 is enabled to translate up and down along the slot-and-key structure in the z-direction of the shaft 1106 while the disk 1104 and shaft 1106 remain fixed.

FIG. 11C is a top view diagram illustrating a hollowed composite cooling structure with a degree of freedom for an electronics cooling system, according to an embodiment. Here, composite cooling disk 1110 (or simply “disk 1110”) comprises a first portion 1112 configured to be closer to a heat-generating device (not shown here; see, e.g., heat-generating device 106 of FIGS. 1-6, 10D), where the first portion 1112 comprises a thermally conductive first material, i.e., a heat-removing solid, having a first density (e.g., copper). Disk 1110 further comprises a second portion 1114 configured to be farther from the heat-generating device, where the second portion 1114 comprises a hollowed out volume (a void or absence of material) and a rotational shaft 1116 configured for being driven (e.g., by a motor) to move the first portion 1112 of disk 1110 over a surface of a heat-generating device (e.g., in a substantially parallel plane). Here also, movement of the disk 1110 over the surface of the heat-generating device facilitates transfer of heat generated by the heat-generating device to the first portion 1112 of disk 1110 and physically moves the heat transferred to the disk 1110 away from the heat-generating device.

According to an embodiment, the disk 1110 may comprise a slot-and-key cylinder 1115 extending through and coaxial with the first portion 1112, and through which the rotational shaft 1116 extends. In the case of a cooling disk such as disk 1110, a slot-and-key arrangement is utilized about the shaft 1116 to enable a z-direction degree of freedom for the first portion 1112 such that in response to any lift force provided by an FDB, the first portion 1112 is enabled to translate up and down along the slot-and-key structure (e.g., cylinder 1115) in the z-direction while the shaft 1116 (and cylinder 1115, if so configured) remains fixed.

In view of the foregoing, described herein are approaches to cooling semiconductor chips, especially useful in the context of cooling ultra-high heat flux devices such as some CPUs and GPUs. Because the high-thermal-conductivity solid structure is continuously moving, a continuous cycle of heat transfer, physical movement, and dissipation for cooling the heat-generating device is provided. Furthermore, addition of a relatively light-weight material or a cavity to the moving solid conductive structure is utilized to reduce the weight of a cooling disk or cylinder employed in such an electronics cooling system, where the solid cooling structure may be configured to substantially match the buoyancy created by a liquid or liquid metal in which the solid is submerged such that the force to support the cooling structure is reduced. Thus, bearing life can significantly improve and/or a different kind of bearing can be used, such as a fluid dynamic bearing rather than a ball bearing.

### Extensions and Alternatives

In the foregoing description, embodiments of the invention have been described with reference to numerous specific details that may vary from implementation to implementation. Therefore, various modifications and changes may be made thereto without departing from the broader spirit and scope of the embodiments. Thus, the sole and exclusive indicator of what is the invention, and is intended by the applicant(s) to be the invention, is the set of claims that issue from this application, in the specific form in which such claims issue, including any subsequent correction. Any definitions expressly set forth herein for terms contained in such claims shall govern the meaning of such terms as used in the claims. Hence, no limitation, element, property, feature, advantage, or attribute that is not expressly recited in a claim should limit the scope of such claim in any way. The specification and drawings are, accordingly, to be regarded in an illustrative rather than a restrictive sense.

In addition, in this description certain process steps may be set forth in a particular order, and alphabetic and alphanumeric labels may be used to identify certain steps. Unless specifically stated in the description, embodiments are not necessarily limited to any particular order of carrying out such steps. In particular, the labels are used merely for convenient identification of steps and are not intended to specify or require a particular order of carrying out such steps.

What is claimed is:

1. A system comprising:
a thermally conductive structure configured for moving over a surface of a heat-generating device, wherein the structure comprises:
a first portion closer to the heat-generating device and comprising a thermally conductive first material having a first density, and
a second portion farther from the heat-generating device and comprising a second material having a second density less than the first density; and
wherein movement of the structure over the surface of the heat-generating device facilitates transfer of heat generated by the heat-generating device to the structure and physically moves the heat transferred to the structure away from the heat-generating device.

2. The system of claim 1, further comprising:
a liquid metal in which the structure is submerged;
wherein a volume of the second material is configured such that the total weight of the structure approaches a buoyant force of the liquid metal.

3. The system of claim 2, wherein the second portion comprises one or more cavities filled with a gas.

4. The system of claim 2, wherein:
the structure comprises a disk positioned in a plane substantially parallel to the heat-generating device; and
the disk is configured to rotate in the plane such that at least a portion of the disk passes over the surface of the heat-generating device.

5. The system of claim 4, wherein:
the first portion comprises a ring; and
the second portion comprises a disk or a cylinder disposed at least in part within the ring.

6. The system of claim 5, wherein:
the second portion is fixed to a rotational shaft; and
the first portion is free to translate along a direction of the shaft.

7. The system of claim 4, wherein:
the first portion comprises a first disk; and
the second portion comprises a second disk coupled with the first disk.

8. The system of claim 1, wherein:
the first material comprises copper; and
the second material comprises plastic.

9. The system of claim 1, wherein:
the structure comprises a cylinder having a major axis positioned substantially parallel to the surface of the heat-generating device; and
the cylinder is configured to rotate over the heat-generating device such that an outer surface of the cylinder passes over the surface of the heat-generating device.

10. The system of claim 9, wherein:
the first portion comprises an annular cylinder; and
the second portion comprises a disk disposed within the cylinder.

11. The system of claim 1, further comprising:
a liquid metal in which the structure is submerged;
an enclosure in which the structure and the liquid metal are enclosed; and
means, external to the enclosure, for dissipating the heat transferred to the structure.

12. The system of claim 11, wherein the liquid metal comprises a liquid metal from a group consisting of InGa (Indium-Gallium) and InGaSn (Indium-Gallium-Tin).

13. A method for removing heat from a heat-generating device, the method comprising:
moving a thermally conductive structure over a surface of a heat-generating device, wherein the structure comprises:
a first portion closer to the heat-generating device and comprising a thermally conductive first material having a first density, and
a second portion farther from the heat-generating device and comprising a second material having a second density less than the first density; and
wherein the movement of the structure over the surface of the heat-generating device (i) encourages transfer of heat generated by the heat-generating device to the structure via a liquid positioned at least between the structure and the heat-generating device and (ii) physically moves the heat transferred to the structure away from the heat-generating device.

14. The method of claim 13, wherein moving the structure includes moving the structure having a volume of the second material configured such that the total weight of the structure approaches a buoyant force of the liquid in which the structure is submerged.

15. The method of claim 14, wherein moving the structure includes rotating a disk structure positioned in a plane substantially parallel to the heat-generating device, such that at least a portion of the disk structure passes over the surface of the heat-generating device.

16. The method of claim 15, wherein:
rotating the disk structure includes rotating the disk structure including the first portion comprising a ring and the second portion comprising a disk or a cylinder disposed at least in part within the ring; and
the second portion is fixed to a rotational shaft and the first portion is free to translate along a direction of the shaft.

17. The method of claim 14, wherein moving the structure includes rotating a cylinder structure having a major axis positioned substantially parallel to the surface of the heat-generating device, such that an outer surface of the cylinder passes over the surface of the heat-generating device.

18. An electronics cooling system comprising:
a thermally conductive structure configured for moving over a heat-emanating surface of a heat-generating chip comprising one or more electronic circuits, wherein the structure comprises:
a first portion closer to the heat-generating chip and comprising copper having a first density, and
a second portion farther from the heat-generating chip and comprising a second material having a second density less than the first density;
a liquid metal in which the structure is submerged;
an enclosure housing the structure and the liquid metal; and
means, external to the enclosure, for dissipating the heat transferred to the structure from the heat-generating chip;
wherein:
movement of the structure over the heat-emanating surface of the heat-generating chip promotes transfer of heat generated by the heat-generating chip to the copper structure via the liquid metal and physically moves the heat transferred to the copper structure away from the heat-generating chip for further removal from within the enclosure by the means for dissipating, and
a volume of the second material is configured such that the total weight of the structure approaches a buoyant force of the liquid metal.

19. The electronics cooling system of claim 18, wherein:
the second portion is fixed to a rotational shaft; and
the first portion is free to translate along a direction of the shaft.

20. The electronics cooling system of claim 18, wherein the second portion comprises one or more cavities filled with a gas.
